(19) United States
(12) Patent Application Publication
(10) Pub. No.: US 2004/0183186 A1
(43) Pub. Date: Sep. 23, 2004

(54) Low-profile electronic circuit module and method for manufacturing the same

(75) Inventor: Yoshitaka Hirose, Fukushima-ken (JP)

Correspondence Address: Brinks Hofer Gilson & Lione, P.O. Box 10395, Chicago, IL, 60610, US

(73) Assignee: Alps Electric Co., Ltd.

(21) Appl. No.: 10/801,317

(22) Filed: Mar. 16, 2004

(30) Foreign Application Priority Data
Mar. 20, 2003 (JP) 2003-078121

(51) Int. Cl. H01L 23/02

(52) U.S. Cl. 257/690

(57) ABSTRACT

A circuit board having lands provided on the top surface of the circuit board and the bottom surface of a recess formed in the top surface and a metal mask having a projection on the bottom surface thereof are prepared. Solder cream is applied to the lands using the metal mask. Then, chip components and a flip chip IC are placed on the solder cream, and the circuit board is put into a reflow oven where the solder cream is melted and solidified so that external terminals of the chip components are reflow-soldered on the lands on the top surface of the circuit board and solder balls of the flip chip IC are reflow-soldered on the lands on the bottom surface of the recess.

This application claims the benefit of Japanese Patent Application No.: 2003-078121, filed on Mar. 30, 2003, which is incorporated herein by reference.

### BACKGROUND OF THE INVENTION

1. Field of the Invention

The present invention relates to electronic circuit modules in which various surface-mount electronic components are soldered on a circuit board and methods for manufacturing the electronic circuit modules. More specifically, the present invention relates to an electronic circuit module in which the surface-mount electronic components include chip components, such as a chip resistor and a chip capacitor, and a flip chip IC of a ball grid array (BGA) type or a bump chip carrier (BCC) type and a method for manufacturing the electronic circuit module.

2. Description of the Related Art

Recently, the size of electronic devices has been reduced and electronic circuit modules have been developed in which surface-mount electronic components, such as chip components-and semiconductor integrated circuit (IC) components are mounted on a circuit board at high density.

As a first example of such an electronic circuit module, Japanese Unexamined Patent Application Publication No. 7-211854 discloses a module in which chip components and a flip chip IC are reflow-soldered on a plurality of lands arranged on the surface of a circuit board. When the electronic circuit module is manufactured, solder cream is applied to each of the lands on the circuit board using a metal mask, and the chip components and the flip chip IC are placed on the solder cream. Then, the circuit board is put in a reflow oven so that the chip components and the flip chip IC are reflow-soldered on the corresponding lands.

In addition, as a second example, an electronic circuit module in which the circuit components mounted on the circuit board include chip components which are reflow-soldered on lands and an IC bare chip which is adhered to the circuit board and is connected to the lands by wire bonding or with stud bumps is also known in the art.

In the electronic circuit module according to the first example in which the chip components and the flip chip IC are reflow-soldered, the thickness of the electronic circuit module is determined by the height of the flip chip IC which projects from the surface of the circuit board since the flip chip IC is larger than the chip components. This limits the reduction in is the thickness of the electronic circuit module.

In comparison, the thickness of the electronic circuit module according to the second example in which the IC bare chip is mounted on the circuit board can be reduced since the height of the bare chip is less than that of the flip chip IC. However, since the bare chip cannot be reflow-soldered like the chip components, it must be connected to the lands by wire bonding or with stud bumps. Accordingly, the manufacturing process is complex and an expensive mounting machine is required. Thus, there is a problem in that the total cost of the electronic circuit module increases.

### SUMMARY OF THE INVENTION

In view of the above-described situation, embodiments of the present invention provide an inexpensive, low-profile electronic circuit module.

A circuit board according to an embodiment of the present invention includes a circuit board having a recess in a surface of the circuit board; and lands which are arranged on the surface of the circuit board and the bottom surface of the recess. An electronic circuit module according to the present invention includes the circuit board as described above and surface-mount electronic components which may be reflow-soldered on the lands.

In the electronic circuit module which is constructed as described above, even when one of the surface-mount electronic components which is mounted on the bottom surface of the recess has a greater height than the other top-surface-mounted surface-mount electronic components, the amount by which the surface-mount electronic component mounted on the bottom surface of the recess projects from the surface of the circuit board is reduced by the amount corresponding to the depth of the recess. Therefore, the thickness of the electronic circuit module may be reduced. In addition, since the surface-mount electronic components may be reflow-soldered on the lands arranged on the surface of the circuit board and the bottom surface of the recess, all of the surface-mount electronic components can be attached to the circuit board in a single reflow-soldering process. Therefore, the manufacturing cost can be reduced and an inexpensive electronic circuit module can be obtained. In the electronic circuit module, the surface-mount electronic component mounted on the bottom surface of the recess is a preferably flip chip IC or other component with increased height and the other lesser height surface-mount electronic components which are mounted on the surface of the circuit board may be chip components. Components with increased height include all forms of electronic components, whether active or passive, such as semiconductor integrated circuits (IC), inductors, capacitors or resistors or modules containing combinations thereof. Increased height components may be necessary due to technical, standardization, cost or manufacturing considerations.

In addition, in order to attain the above-described advantages, a method for manufacturing an electronic circuit module according to the present invention includes the steps of forming a circuit board having a recess in its surface; providing lands on the surface of the circuit board and the bottom surface of the recess; placing a metal mask on the surface of the circuit board, the metal mask having a flat top surface and a bottom surface provided with a projection, and positioning the projection with respect to the recess; applying solder cream to each of the lands through the metal mask; placing surface-mount electronic components on the lands with the solder cream interposed between each of the surface-mount electronic components and the corresponding lands; and putting the circuit board in a reflow oven and reflow-soldering the surface-mount electronic components to the corresponding lands.

In the electronic circuit module which is manufactured by the above-described method, the solder cream is applied to each of the lands arranged on the surface of the circuit board and the bottom surface of the recess using a metal mask having a projection from the bottom surface of the mask. Then, the surface-mount electronic components are placed on the solder cream and are reflow-soldered on the corresponding lands. Accordingly, all of the surface-mount electronic components may be attached to the circuit board in a single reflow-soldering process. Therefore, the manufacturing cost can be reduced and an inexpensive electronic circuit module can be obtained. In addition, even when one of the surface-mount electronic components which is mounted on the bottom surface of the recess has a greater height than the other surface-mount electronic components, the amount by which the surface-mount electronic component mounted on the bottom surface of the recess projects from the surface of the circuit board is reduced by the amount corresponding to the depth of the recess. Therefore, the thickness of the electronic circuit module can be reduced. Where necessary for circuit layout considerations, standard height chips or other components which would conventionally be mounted on the surface of the circuit board may also be mounted in the recess.

### BRIEF DESCRIPTION OF THE DRAWINGS

FIG. 1 is a sectional view of an electronic circuit module according to an aspect of the present invention;

FIGS. 2A to 2D are sectional views showing a manufacturing process of the electronic circuit module; and

FIG. 3 is a flowchart of the manufacturing process of the electronic circuit module.

### DESCRIPTION OF THE INVENTION

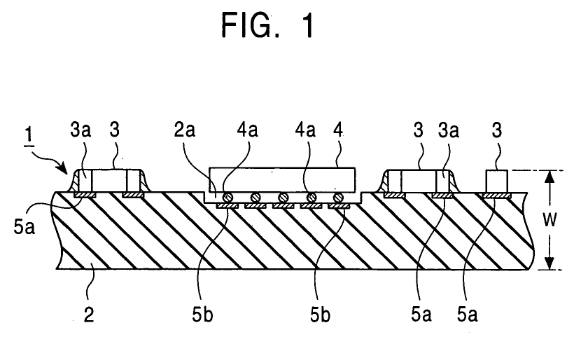

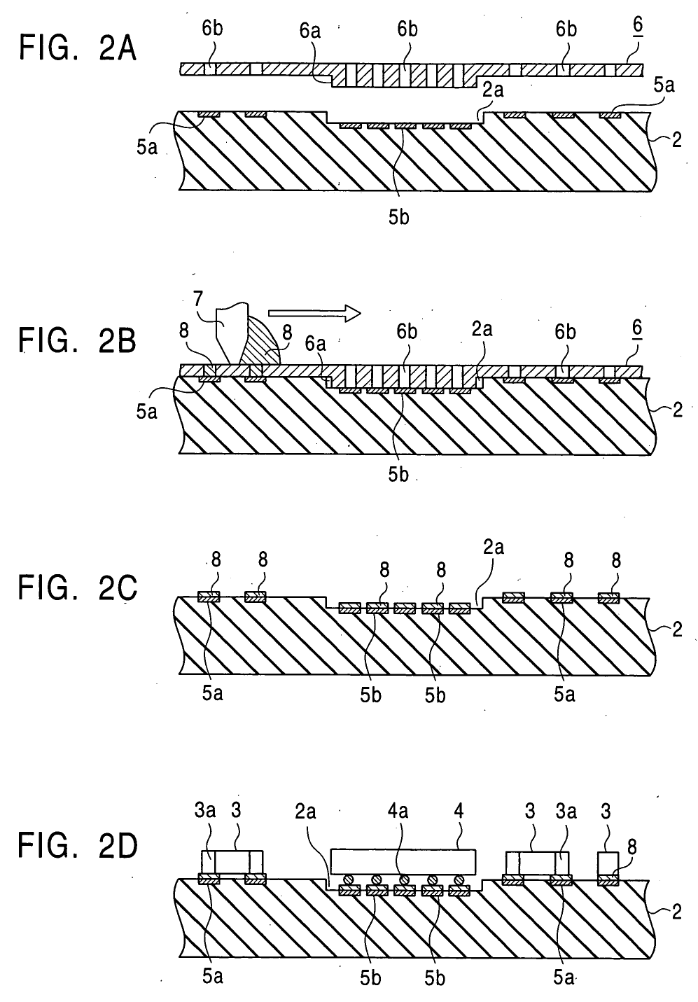

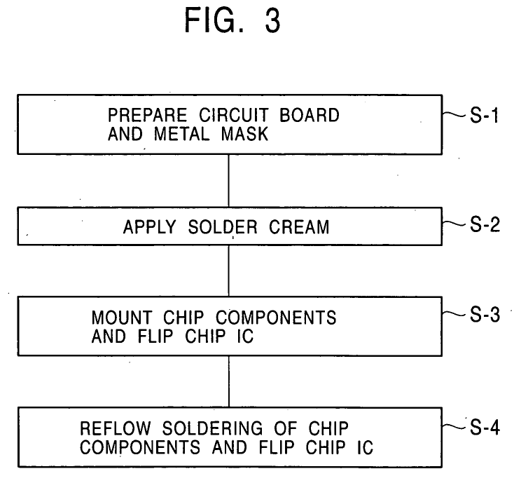

An arrangement according to the present invention and a method of manufacturing the same will be described below with reference to the accompanying drawings. FIG. 1 is a sectional view of a circuit card and electronic circuit module according to an aspect of the present invention, FIGS. 2A to 2D are sectional views showing a manufacturing process of the electronic circuit module, and FIG. 3 is a flowchart of the manufacturing process of the electronic circuit module.

As shown in FIG. 1, an electronic circuit module 1 according to an aspect of the present invention includes a circuit board 2 which may be comprised of an alumina, ceramic or epoxy-glass substrate or other suitable material and which has a recess 2a in the top surface thereof and various kinds of chip components 3 and a flip chip IC 4 or other increased height component which are mounted on the circuit board 2. The chip components 3 and the flip chip IC 4 may be reflow-soldered on lands 5 which are arranged on the top surface of the circuit board 2 and the bottom surface of the recess 2a. The circuit board 2 may be a single layer board or comprised of multiple layers.

The circuit board 2 may serve as a surface mount module which may also be mounted on a motherboard (not shown) by reflow soldering, and is provided with a plurality of connecting terminals on the side and the bottom surfaces of the circuit board 2 (not shown) which may be reflow-soldered on connection lands arranged on the motherboard. The planar dimensions of aperture of the recess 2a formed in the top surface of the circuit board 2 are slightly larger than the peripheral size of the flip chip IC 4 so as to accommodate the component and any connecting leads. The depth of the recess is preferably substantially equal to the difference in height between the highest component to be mounted in the recess and the height of the chip components mounted on the top surface of the circuit board 2 although this is not required or practical for all component sizes and mounting arrangements. Any depth of the recess serves to reduce the overall height of the electronic circuit module. A plurality of lands 5 are arranged on the top surface of the circuit board 2 and the bottom surface of the recess 2a, and each land is electrically connected to a wiring pattern (not shown). For illustration, the lands arranged on the top surface of the circuit board 2 are denoted by 5a and the lands arranged on the bottom surface of the recess 2a are denoted by 5b.

Each of the chip components 3 may be a chip capacitor, a chip resistor or other chip component, and external terminals 3a of the chip components 3 may be reflow-soldered on the lands 5a on the top surface of the circuit board 2. The flip-chip IC 4 is of a BGA type or a BCC type or other packaged component arrangement. In the present illustration, the flip chip IC 4 is of the BGA type in which external connection lands are arranged on the bottom surface of the flip chip IC 4 in a grid pattern and solder balls 4a are adhered on the external connection lands. The solder balls 4a of the flip chip IC 4 are reflow-soldered on the lands 5b arranged on the bottom surface of the recess 2a.

Next, a method for manufacturing the electronic circuit module 1 having the above-described construction will be described below with reference to FIGS. 2A to 2D and 3.

First, as in Step 1 of the flowchart shown in FIG. 3, the circuit board 2 and a metal mask 6, which may be stainless steel or other suitable material, are prepared. As described above, the circuit board 2 has the recess 2a in the top surface thereof, and the lands 5a and 5b are provided on the top surface of the circuit board 2 and the bottom surface of the recess 2a, respectively. In addition, as shown in FIG. 2A, the metal mask 6 has a projection 6a on the bottom surface thereof, and a plurality of through holes 6b are provided in the metal mask 6 including a region having the projection 6a. The projection 6a and the through holes 6b may be formed by etching or laser processing, and the distance by which the projection 6a projects from the bottom surface of the metal mask may be set to be the same as the depth of the recess 2a formed in the circuit board 2.

Next, as in Step 2 of the flowchart shown in FIG. 3, solder cream 8 is applied to each of the lands 5a and 5b provided on the circuit board 2 using the metal mask 6. In this step, first, the metal mask 6 is placed on the circuit board 2 and is positioned with respect to the circuit board 2 such that the projection 6a is inserted into the recess 2a. Then, as shown in FIG. 2B, the solder cream 8 is supplied into the through holes 6b in the metal mask 6 with a squeegee 7. Then, the metal mask 6 is removed from the circuit board 2. Accordingly, as shown in FIG. 2C, the solder cream 8 is applied to each of the lands 5a and 5b provided on the circuit board 2. Since the metal mask 6 has the projection 6a which may come into contact, or close proximity, with the bottom surface of the recess 2a, the solder cream 8 can be applied to the lands Sa and 5b provided on the top surface of the circuit board 2 and the bottom surface of the recess 2a, respectively, at the same time. The lower surface of the metal mask 6 may be either in contact with, or in close proximity to, the top surface of the circuit card 2 and the bottom surface of the recess 2a during the application of the solder cream 8.

Next, as in Step 3 of the flowchart shown in FIG. 3, the chip components 3 and the flip chip IC 4 are mounted on the lands 5a and 5b, respectively, with the solder cream 8 provided therebetween. In this step, as shown in FIG. 2D, the chip components 3 are placed on the solder cream 8 applied to the lands 5a provided on the top surface of the circuit board 2 and the flip chip IC 4 is placed on the solder cream 8 applied to the lands 5b provided on the bottom surface of the recess 2a.

Next, as in Step 4 of the flowchart shown in FIG. 3, the chip components 3 and the flip chip IC 4 are reflow-soldered on the corresponding lands 5a and 5b, and thus the electronic circuit module 1 shown in FIG. 1 is completed. More specifically, the circuit board 2 on which the chip components 3 and the flip chip IC 4 are placed is put in a reflow oven (not shown), and the solder-cream 8 is melted and solidified in the reflow oven so that the external terminals 3a of the chip components 3 are reflow-soldered on the lands 5a arranged on the top surface of the circuit board 2 and the solder balls 4a of the flip chip IC 4 (or the external terminals of a packaged device) are reflow-soldered on the lands 5b arranged on the bottom surface of the recess 2a, as shown in FIG. 1.

As described above, in the electronic circuit module 1 according to the present embodiment, the recess 2a is formed in the top surface of the circuit board 2 and the solder balls 4a of the flip chip IC 4 are reflow-soldered on the lands 5b arranged on the bottom surface of the recess 2a. Accordingly, the amount by which the flip chip IC 4 projects from the surface of the circuit board 2 can be reduced by the amount corresponding to the depth of the recess 2a. Therefore, although the flip chip IC 4, may have a greater height than the chip components 3, is mounted on the circuit board 2 along with the chip components 3, the thickness of the electronic circuit module 1 (indicated by W in FIG. 1) may be reduced with respect to an arrangement where all of the components are mounted on the top surface of the circuit card 2. In addition, when the electronic circuit module 1 is manufactured, the metal mask 6 having the projection 6a on the back surface thereof is used and the solder cream 8 is applied while the projection 6a may be in contact with the bottom surface of the recess 2a. Therefore, the solder cream 8 may be applied to the lands 5a provided on the top surface of the circuit board 2 and the lands 5b provided on the bottom surface of the recess 2a at the same time. Since the solder cream 8 is applied to the lands 5a and 5b on the circuit board 2 at the same time using the metal mask 6 and the chip components 3 and the flip chip IC 4 are placed on the solder cream 8 and reflow-soldered on the lands 5a and 5b, respectively, all of the chip components 3 and the flip chip IC 4 can be mounted on the circuit board 2 in a single reflow-soldering process. Therefore, it is not necessary to use an expensive and complex mounting machine as in the case where an IC bare chip is attached by wire bonding or with stud bumps, and the low-profile electronic circuit module 1 can be manufactured at lower cost.

In the above-described arrangement, the flip chip IC 4 of the BGA type is described as an example of the surface-mount electronic component which is reflow-soldered in the recess 2a of the circuit board 2. However, a flip chip IC of the BCC type and surface-mount electronic components other than the flip chip IC may also be used. In addition, other components which may require additional soldering operations, such as discrete leaded components may be disposed in the recess 2a of the circuit board 2 so that the overall height of the electronic module may be reduced.

It will be understood that the above descriptions are merely illustrative of the invention, but it will be apparent to persons skilled in the art that many modifications and alterations to the arrangements and manufacturing method are practical. The invention is therefore limited only by that which is claimed.

What is claimed is:

1. An electronic circuit module comprising:
a circuit board having a recess in a surface of the circuit board;
lands which are arranged on the surface of the circuit board and a bottom surface of the recess; and
electronic components which are soldered on the lands.

2. The electronic circuit module according to claim 1, wherein the electronic components are surface-mount electronic components.

3. The electronic circuit module according to claim 1, wherein the circuit board is a multi-layer assembly.

4. The electronic circuit module according to claim 2, wherein the surface-mount electronic components include chip components which are soldered to the lands on the surface of the circuit board and a flip chip IC which is soldered to the lands on the bottom surface of the recess.

5. The electronic circuit module according to claim 4, wherein the flip chip IC is a BGA type or a BCC type.

6. The electronic circuit module according to claim 1, wherein at least one of electronic components is soldered to the lands on the bottom surface of the at least one of a packaged semiconductor integrated circuit and a passive chip component.

7. The electronic circuit module according to claim 1, wherein the soldering is reflow-soldering.

8. The electronic circuit module according to claim 7, wherein all of the electronic components are reflow-soldered in a single operation.

9. The electronic circuit module according to claim 2, wherein the surface-mount electronic components include chip components which are soldered to the lands on the surface of the circuit board and a packaged electronic component which is soldered to the lands on the bottom surface of the recess.

10. The electronic circuit module according to claim 2, wherein the circuit board has a substrate comprised of one of an alumina, a ceramic and a glass-epoxy material.

11. The electronic circuit module according to claim 9, wherein the packaged electronic component comprises at least a plurality of passive electronic components.

12. The electronic circuit module according to claim 9, wherein the packaged electronic component comprises at least one active electronic component.

13. A circuit board comprising:
a substrate having a recess in a top surface surface thereof; and
lands which are arranged on the surface of the substrate and on a bottom surface of the recess.

14. The circuit board as in claim 13, wherein a depth of the recess is substantially equal to a height difference between a first component to be mounted on the top surface of the substrate and a second component to be mounted on the bottom surface of the recess.

15. The circuit board according to claim 13, wherein the substrate is comprised of one of an alumina, a ceramic and a glass-epoxy material.

16. The circuit board according to claim 15, wherein the substrate is comprised of multiple layers.

17. The circuit board according to claim 13, wherein the lands are dimensioned so as to permit attachment of components by reflow soldering.

18. The circuit board according to claim 13, further comprising:
connecting terminals disposed at on at least one of a side and a bottom surface of the substrate,
wherein the connecting terminals are dimensioned so as to permit attachment of the circuit board to a motherboard by reflow soldering.

19. A method for manufacturing an electronic circuit module comprising:
forming a recess in a surface of a circuit board;
providing lands on the surface of the circuit board and a bottom surface of the recess;
applying solder cream to each of the lands for which a reflow-soldered connection is to be made;
placing surface-mount electronic components on the lands with the solder cream interposed between each of the surface-mount electronic components and the corresponding lands; and
reflow-soldering the surface-mount electronic components to the corresponding lands.

20. The method according to claim 19, wherein the solder cream is applied to the lands by placing a metal mask on the surface of the circuit board, the metal mask having a flat top surface and a bottom surface provided with a projection, positioning the projection with respect to the recess, applying solder cream to the top surface of the metal mask, and spreading the solder cream over the top.

21. The method according to claim 20, wherein the solder cream is applied to the lands on the surface of the circuit board and the lands on the bottom surface of the recess in a single spreading operation.

22. The method according to claim 21, wherein all of the surface-mount components are reflow-soldered to the corresponding lands on the surface of the circuit board and the bottom surface of the recess in a single reflow soldering operation.

23. A solder mask comprising;
a metal sheet having a flat upper surface;
a protrusion in a bottom surface of the metal sheet corresponding in position to a recess formed in a surface of a substrate and sized such that the protrusion may be inserted in the recess; and
apertures formed in the metal sheet,
wherein the apertures are formed in positions corresponding to the location of lands on the surface of the substrate and lands on the bottom surface of the recess.

24. The solder mask according to claim 23, wherein the apertures are sized to permit a predetermined amount of solder cream to be applied to each land.

25. The solder mask according to claim 23, wherein a height of the protrusion is substantially equal to a depth of the recess.

26. The solder mask according to claim 23, wherein the metal sheet is comprised of stainless steel.

27. An electronic circuit module having a reduced overall height comprising:
a substrate;
means for connecting components to a printed wiring pattern; and
means for recessing components below a top surface of the substrate.

28. The electronic circuit module according to claim 27, having a means for connecting the printed wiring pattern to a motherboard.

29. A circuit board comprising:
a substrate;
means for mounting components at multiple heights with respect to a top surface of the substrate; and
means for connecting the components to a wiring pattern.
